(19) United States
(12) Patent Application Publication
(10) Pub. No.: US 2016/0278248 A1
(43) Pub. Date: Sep. 22, 2016

(54) PROTECTIVE SHEATH FOR ELECTRONIC DEVICE

(71) Applicant: Aliner Industries Inc., Taipei (TW)

(72) Inventor: Meng Chieh WU, Taipei (TW)

(21) Appl. No.: 14/663,489

(22) Filed: Mar. 20, 2015

(51) Int. Cl. H05K 9/00; H05K 5/02

(52) U.S. Cl. CPC H05K 9/0001; H05K 5/0247

(57) ABSTRACT

A protective shell or sheath for an electronic facility includes a receptacle having a chamber formed by a peripheral wall, and a cover having a plate for engaging onto the peripheral wall and for shielding the chamber of the receptacle, the cover includes a peripheral fence extended downwardly from the plate and formed integral with the plate for engaging with the peripheral wall of the receptacle. The cover includes an engaging element for engaging with the peripheral wall. The receptacle includes an engaging member formed in an upper portion of the peripheral wall for engaging with the engaging element of the cover.

### BACKGROUND OF THE INVENTION

1. Field of the Invention

The present invention relates to a protective shell or shield or sheath for electronic devices, and more particularly to a protective shell or shield or sheath for attaching or mounting or securing onto an electronic device or portable or mobile phone for shielding and protecting the electronic device and for avoiding an electromagnetic interference problem.

2. Description of the Prior Art

Various kinds of electronic devices, such as mobile or portable phones, multimedia players, personal digital assistants, palmtop computers, palmtop game devices, television top boxes, cable modems, and handheld satellite navigators, etc., for such as internet intercommunication purposes have been widely used today, and such electronic devices are usually small and light, and convenient for the user to use.

For example, U.S. Patent Application No. 2002/0127975 to Hsu, U.S. Patent Application No. 2010/0124040 to Diebel et al., U.S. Patent Application No. 2011/0077061 to Danze et al., U.S. Patent Application No. 2012/0088555 to Hu, U.S. Patent Application No. 2012/0231859 to Makino et al., U.S. Patent Application No. 2012/0261288 to Lach et al., U.S. Patent Application No. 2012/0329532 to Ko, U.S. Patent Application No. 2013/0063904 to Hsu et al., U.S. Pat. No. 4,718,742 to Utoh et al., and U.S. Pat. No. 8,755,851 to Kim et al. disclose several of the typical electronic devices or portable or mobile phones each comprising a typical housing or receptacle for receiving and containing the electronic devices or apparatuses or facilities that may generate or receive electrical or electromagnetic signals or the like.

The typical electronic devices may have been improved into the 4th generation (4G) for internet intercommunication facilities, but electromagnetic interference (EMI) problems may be occurred between the electronic devices. The housing or receptacle for the typical electronic devices or apparatuses or facilities normally include two or more housing members or elements assembled together. However, the housings or receptacles may include one or more gaps or slits or openings formed between the two or more housing members or elements, such that noises may have a good chance to enter into the receptacle and such that electromagnetic interference (EMI) problems may still be occurred for the typical electronic devices or apparatuses or facilities.

The present invention has arisen to mitigate and/or obviate the afore-described disadvantages of the conventional protective sheath or shield for electronic devices or facilities.

### SUMMARY OF THE INVENTION

The primary objective of the present invention is to provide a protective shell or shield or sheath for attaching or mounting or securing onto an electronic device or portable or mobile phone and for shielding and protecting the electronic devices and for preventing the noises from entering into the receptacle of the protective sheath and for preventing the electromagnetic interference problems from being occurred for the electronic devices.

In accordance with one aspect of the invention, there is provided a protective sheath for an electronic facility comprising a receptacle including a chamber formed therein and defined by a peripheral wall, and a cover including a plate for engaging onto the peripheral wall and for shielding the chamber of the receptacle and for preventing the noises from entering into the receptacle and for preventing the electromagnetic interference problems from being occurred for the electronic facility that is contained within the chamber of the receptacle, the cover including a peripheral fence extended downwardly from the plate and formed integral with the plate for engaging with the peripheral wall of the receptacle and for preventing the cover from being disengaged or separated from the receptacle.

The cover includes an engaging element for engaging with the peripheral wall and for making a water or air tight seal between the cover and the receptacle. The receptacle includes an engaging member formed in an upper portion of the peripheral wall for engaging with the engaging element of the cover.

For example, the engaging element of the cover may be selected from a peripheral projection extended downwardly from the plate for engaging with the engaging member of the peripheral wall. The engaging member may be selected from a peripheral recess formed in the upper portion of the peripheral wall for snugly engaging with the peripheral projection of the cover and for preventing the noises from entering into the receptacle.

The cover includes at least one catch extended from the peripheral fence for engaging with the peripheral wall and for preventing the cover from being disengaged or separated from the receptacle. The receptacle includes a peripheral shoulder formed in an outer peripheral portion of the peripheral wall for engaging with the catch of the cover and for further preventing the cover from being disengaged or separated from the receptacle.

The cover includes an opening formed in the peripheral fence, and the receptacle includes a radio frequency element extended outwardly from the peripheral wall for engaging with the opening of the cover. The radio frequency element is preferably formed integral with the peripheral wall for preventing gaps or slits or openings from being formed between the peripheral wall and the radio frequency element and for preventing the noises from entering into the receptacle.

The cover includes at least one notch formed therein for increasing a flexibility or resilience of the peripheral fence. The receptacle includes at least one partition engaged in the chamber of the receptacle for separating the chamber of the receptacle into two or more compartments or spaces and for receiving or engaging with various parts or elements of the electronic device.

Further objectives and advantages of the present invention will become apparent from a careful reading of the detailed description provided hereinbelow, with appropriate reference to the accompanying drawings.

### BRIEF DESCRIPTION OF THE DRAWINGS

FIG. 1 is a perspective view of a protective sheath in accordance with the present invention for a portable or mobile phone;

FIG. 2 is an exploded view of the protective sheath;

FIG. 3 is another exploded view of the protective sheath, in which the upper cover is disposed up-side-down;

FIG. 4 is a cross sectional view of the protective sheath, taken along lines 4-4 of FIG. 1;

FIG. 5 is a further exploded view similar to FIG. 2, illustrating the other arrangement of the protective sheath;

FIG. 6 is a still further exploded view similar to FIGS. 2 and 5, illustrating the further arrangement of the protective sheath; and

FIG. 7 is a perspective view illustrating a cover of the protective sheath.

### DETAILED DESCRIPTION OF THE PREFERRED EMBODIMENT

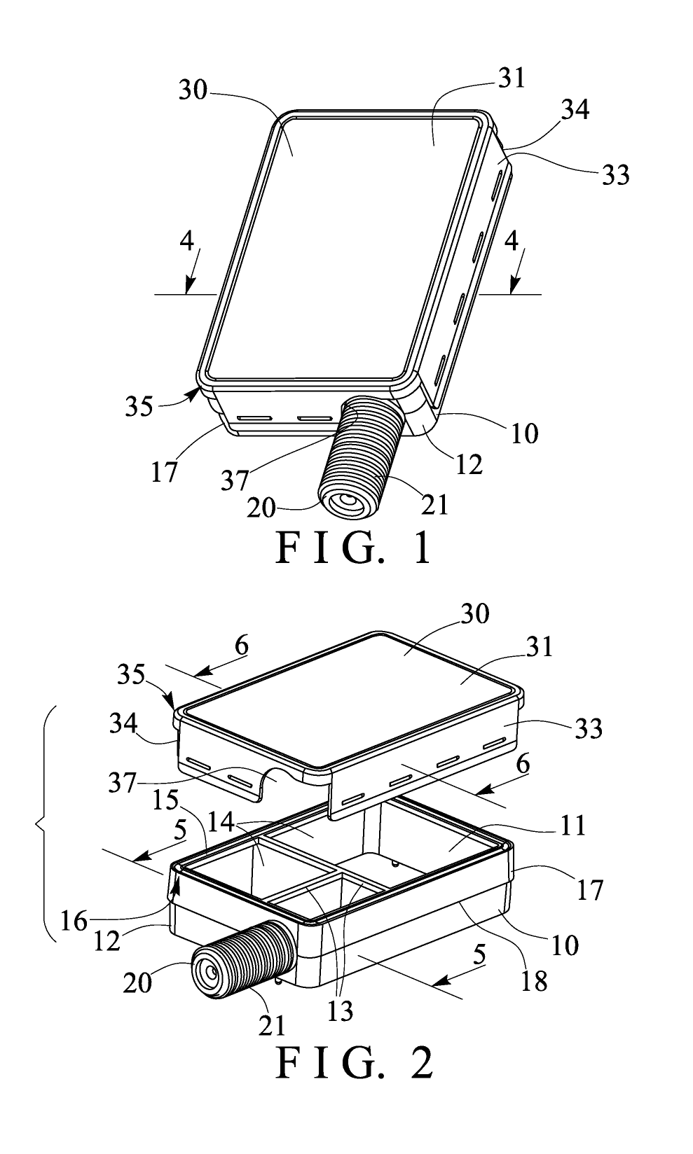

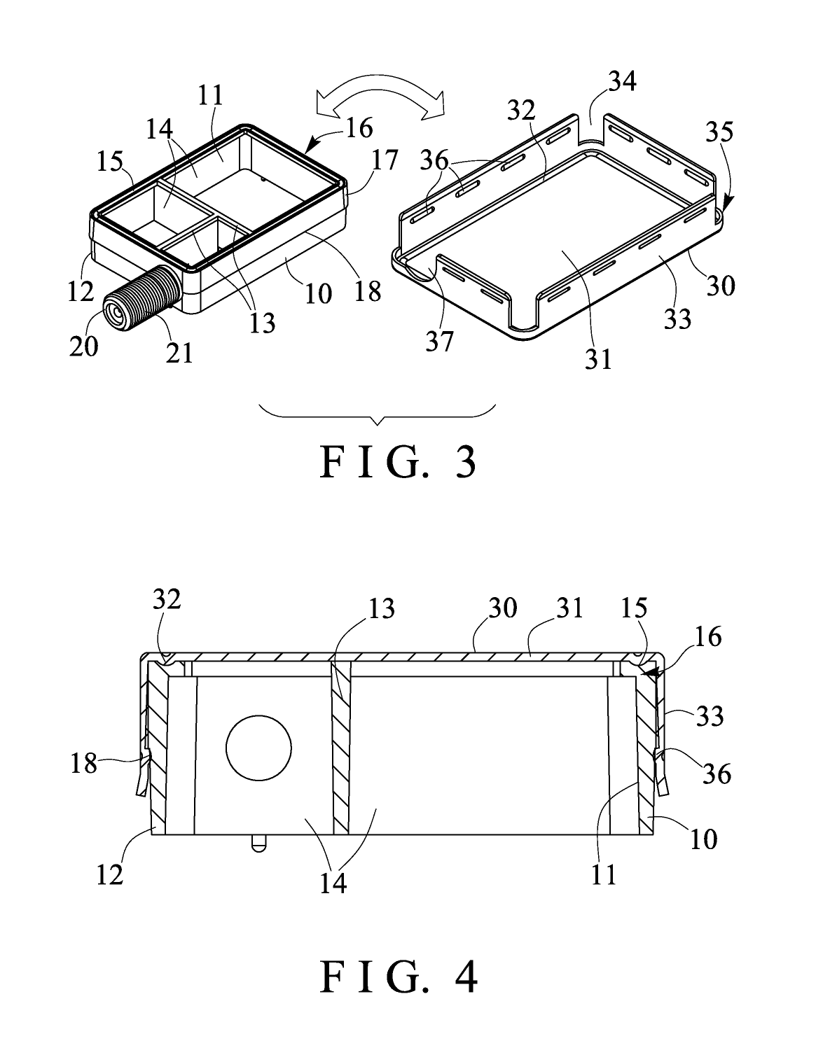

Referring to the drawings, and initially to FIGS. 1-4, a protective sheath in accordance with the present invention comprises a housing or receptacle 10 including a compartment or chamber 11 formed therein and formed or defined by a peripheral wall 12 for receiving or accommodating an electronic device or apparatus or facility (not illustrated), such as the mobile or portable phone, the multimedia player, the personal digital assistant, the palmtop computer, the palmtop game device, the television top box, the cable modem, and the handheld satellite navigator or the like, the electronic device is not related to the present invention and will not be described in further details. The receptacle 10 may include one or more partitions 13 formed or provided therein and engaged in the chamber 11 of the receptacle 10 for separating the chamber 11 of the receptacle 10 into two or more compartments or spaces 14 and for receiving or engaging with various parts or elements of the electronic device (not illustrated).

The receptacle 10 includes an engaging member 15, such as a peripheral rib or protrusion or recess 15 formed in the upper portion 16 of the peripheral wall 12, best shown in FIGS. 2-4. It is preferable, but not necessary that the receptacle 10 includes three or more (such as four) rounded corner areas 17 formed thereon for allowing the receptacle 10 to be easily and quickly and readily removed or disengaged from the mold devices (not illustrated) while molding or manufacturing the receptacle 10, and the receptacle 10 may further include a peripheral shoulder 18 formed in the outer peripheral portion of the peripheral wall 12 also for allowing the receptacle 10 to be easily and quickly and readily removed or disengaged from the mold devices (not illustrated).

As shown in FIGS. 1-3, the receptacle 10 may further include a radio frequency extension or element 20 extended outwardly from the peripheral wall 12, and the radio frequency element 20 includes an outer thread 21 formed or provided thereon for connecting or coupling to antenna devices (not illustrated) or the like and for signal transmitting/receiving purposes. As shown in FIGS. 1-4, the protective sheath further includes a cover 30 having an upper cover plate 31 for engaging onto the upper portion 16 of the peripheral wall 12 and for covering and shielding the chamber 11 of the receptacle 10. The cover 30 may include an engaging element 32, such as a peripheral rib or projection 32 extended downwardly therefrom for engaging with the engaging member or peripheral recess 15 of the peripheral wall 12 and for further solidly and firmly or stably covering and shielding the chamber 11 of the receptacle 10.

The cover 30 further includes a peripheral skirt or fence 33 extended downwardly from the plate 31 and formed integral with the plate 31, and no gaps or slits or openings formed between the plate 31 and the peripheral fence 33 of the cover 30, for contacting or engaging with the peripheral wall 12 of the receptacle 10, and may further include three or more (such as four) openings or notches 34 formed in the corner areas 35 for increasing the flexibility or resilience of the peripheral fence 33 and for allowing the peripheral fence 33 to be resiliently or suitably contacted or engaged with the peripheral wall 12 of the receptacle 10, and may further include one or more projections or catches 36 extended inwardly from the peripheral fence 33 for engaging with the peripheral shoulder 18 of the peripheral wall 12 (FIG. 4) and for solidly and firmly anchoring or retaining the peripheral fence 33 and the cover 30 to the peripheral wall 12 and the receptacle 10. The cover 30 further includes an opening 37 formed in the peripheral fence 33 for receiving or engaging with the radio frequency element 20 (FIG. 1).

In operation, as shown in FIGS. 1 and 4, the plate 31 of the cover 30 may be engaged onto the upper portion 16 of the peripheral wall 12 for covering and shielding the chamber 11 of the receptacle 10, and the projection or engaging element 32 of the cover 30 may be engaged with the engaging member or peripheral recess 15 of the peripheral wall 12 for further solidly and firmly or stably covering and shielding the chamber 11 of the receptacle 10 and for preventing gaps or slits or openings from being formed between the receptacle 10 and the cover 30, and for preventing the noises from entering into the receptacle 10, and for preventing the electromagnetic interference problems from being occurred for the electronic devices that are contained within the chamber 11 of the receptacle 10.

The peripheral fence 33 of the cover 30 may be engaged with the peripheral wall 12 of the receptacle 10 for solidly and firmly anchoring or retaining the peripheral fence 33 and the cover 30 to the peripheral wall 12 and the receptacle 10. The catches 36 of the cover 30 may further be engaged with the peripheral shoulder 18 of the peripheral wall 12 for solidly and firmly anchoring or retaining the peripheral fence 33 and the cover 30 to the peripheral wall 12 and the receptacle 10 and for preventing the projection or engaging element 32 of the cover 30 from being disengaged or separated from the receptacle 10. It is to be noted that the radio frequency element 20 is extended outwardly from the peripheral wall 12 and formed integral with the peripheral wall 12 for preventing gaps or slits or openings from being formed between the peripheral wall 12 and the radio frequency element 20 and for preventing the noises from entering into the receptacle 10.

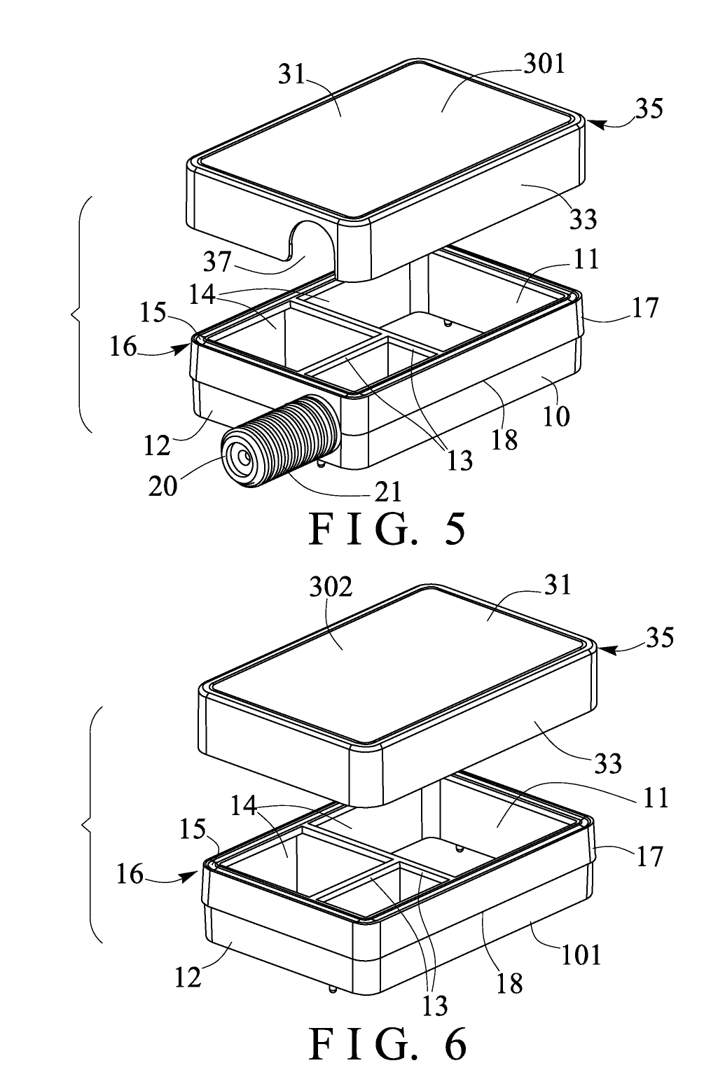

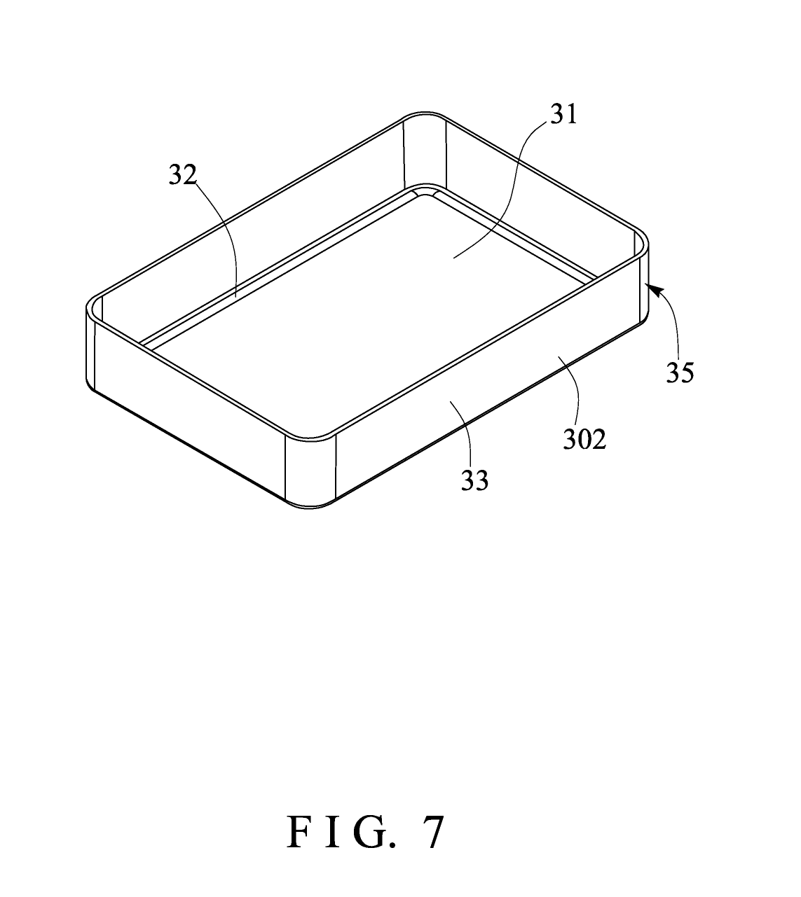

Alternatively, as shown in FIG. 5, the cover 301 may include no notches formed in the corner areas 35, and the peripheral fence 33 may also include a suitable flexibility or resilience for resiliently or suitably contacting or engaging with the peripheral wall 12 of the receptacle 10. Further alternatively, as shown in FIGS. 6 and 7, the cover 302 may include no notches formed in the corner areas 35, and no opening formed in the peripheral fence 33, and the receptacle 101 includes no radio frequency extension or element extended outwardly from the peripheral wall 12. The plate 31 of the cover 301, 302 may also be engaged onto the upper portion 16 of the peripheral wall 12 for covering and shielding the chamber 11 of the receptacle 10, 101 and the projection or engaging element 32 of the cover 301, 302 may also be engaged with the engaging member or peripheral recess 15 of the peripheral wall 12 for further solidly and firmly or stably covering and shielding the chamber 11 of the receptacle 10, 101 and for preventing gaps or slits or openings from being formed between the receptacle 10, 101 and the cover 301, 302, and for preventing the noises from entering into the receptacle 10, 101 and for preventing the electromagnetic interference problems from being occurred for the electronic devices that are contained within the chamber 11 of the receptacle 10, 101.

Accordingly, the protective sheath in accordance with the present invention may be provided for attaching or mounting or securing onto electronic devices or portable or mobile phones and for shielding and protecting the electronic devices and for preventing the noises from entering into the receptacle of the protective sheath and for avoiding the electromagnetic interference problems from being occurred for the electronic devices.

Although this invention has been described with a certain degree of particularity, it is to be understood that the present disclosure has been made by way of example only and that numerous changes in the detailed construction and the combination and arrangement of parts may be resorted to without departing from the spirit and scope of the invention as hereinafter claimed.

I claim:

1. A protective sheath for an electronic facility comprising:
a receptacle including a chamber formed therein and defined by a peripheral wall, and
a cover including a plate for engaging onto said peripheral wall and for shielding said chamber of said receptacle, said cover including a peripheral fence extended downwardly from said plate and formed integral with said plate for engaging with said peripheral wall of said receptacle.

2. The protective sheath as claimed in claim 1, wherein said cover includes an engaging element for engaging with said peripheral wall.

3. The protective sheath as claimed in claim 2, wherein said receptacle includes an engaging member formed in an upper portion of said peripheral wall for engaging with said engaging element of said cover.

4. The protective sheath as claimed in claim 3, wherein said engaging element of said cover is a peripheral projection extended downwardly from said plate for engaging with said engaging member of said peripheral wall.

5. The protective sheath as claimed in claim 4, wherein said engaging member is a peripheral recess formed in said upper portion of said peripheral wall for engaging with said peripheral projection of said cover.

6. The protective sheath as claimed in claim 1, wherein said cover includes at least one catch extended from said peripheral fence for engaging with said peripheral wall.

7. The protective sheath as claimed in claim 6, wherein said receptacle includes a peripheral shoulder formed in an outer peripheral portion of said peripheral wall for engaging with said at least one catch of said cover.

8. The protective sheath as claimed in claim 1, wherein said cover includes an opening formed in said peripheral fence, and said receptacle includes a radio frequency element extended outwardly from said peripheral wall for engaging with said opening of said cover.

9. The protective sheath as claimed in claim 1, wherein said cover includes at least one notch formed therein.

10. The protective sheath as claimed in claim 1, wherein said receptacle includes at least one partition engaged in said chamber of said receptacle.
